(19) United States
(12) Patent Application Publication
(10) Pub. No.: US 2025/0227934 A1
(43) Pub. Date: Jul. 10, 2025

(54) METHODS AND COMPUTER-READABLE MEDIUM RELATED TO FERROELECTRIC MEMORY

(71) Applicant: TAIWAN SEMICONDUCTOR MANUFACTURING COMPANY LTD., HSINCHU (TW)

(72) Inventors: YU-CHUAN SHIH, HSINCHU CITY (TW); YU-KAI CHANG, HSINCHU CITY (TW); PEI-CHUN LIAO, HSINCHU COUNTY (TW); HUAI-YING HUANG, NEW TAIPEI CITY (TW); CHUN-CHIEH LU, TAIPEI CITY (TW); YU-MING LIN, HSINCHU CITY (TW)

(21) Appl. No.: 18/406,238

(22) Filed: Jan. 8, 2024

(51) Int. Cl. H10B 51/30; H01L 29/66; H01L 29/78

(52) U.S. Cl. CPC H10B 51/30; H10D 30/0415; H10D 30/701

(57) ABSTRACT

A method is provided. The method includes applying a first pulse to a ferroelectric memory device, measuring a memory window metric of the ferroelectric memory device, and applying a second pulse to the ferroelectric memory device. The first pulse may have a first voltage magnitude. The second pulse may have a second voltage magnitude. The second voltage magnitude may be determined based at least in part on the measured memory window metric.

### BACKGROUND

With advantages of non-volatility, low power consumption, short programming time, and high read/write endurance, ferroelectric random-access memory (FeRAM) has drawn increasing attention.

Many modern day electronic devices include non-volatile memory. Non-volatile memory is electronic memory that is able to store data in the absence of power. A promising candidate for the next generation of non-volatile memory is ferroelectric random-access memory (FeRAM). FeRAM has a relatively simple structure and is compatible with complementary metal-oxide-semiconductor (CMOS) logic fabrication processes.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic cross sectional view of a semiconductor structure in accordance with some embodiments of the present disclosure.

FIGS. 1A, 1B and 1C are the schematic cross sectional view of several semiconductor structures in accordance with some embodiments of the present disclosure.

FIG. 2A is a chart illustrating a hysteresis curve for ferroelectric material for polarization induced by an applied electrical field, in accordance with some embodiments of the present disclosure.

FIG. 2B is a chart illustrating two threshold voltage (Vₜ) levels for a ferroelectric memory device, in accordance with some embodiments of the present disclosure.

FIG. 3A is a chart illustrating the effect of wake-up processes on the memory window of an exemplary ferroelectric memory device, in accordance with some embodiments of the present disclosure.

FIG. 3B illustrates a pulse train (e.g., voltage pulse train), in accordance with some embodiments of the present disclosure.

FIGS. 3C, 3D, 3E and 3F illustrate exemplary pulse trains (e.g., voltage pulse train), in accordance with some embodiments of the present disclosure.

FIG. 4 illustrates histograms that show the statistical distribution of Iₒₙ and Vₜ of ferroelectric memory devices at different logical states, in accordance with some embodiments of the present disclosure.

FIG. 5 illustrates a pulse train (e.g., voltage pulse train), in accordance with some embodiments of the present disclosure.

FIG. 6A illustrates exemplary effects on Iₒₙ at two different logical states with different amount of pulse voltages during pre-conditioning, in accordance with some embodiments of the present disclosure.

FIG. 6B illustrates an exemplary flowchart, in accordance with some embodiments of the present disclosure.

FIG. 7A illustrates a photo of a layer of ferroelectric material of several different memory units, and exemplary associated hysteresis curves and pre-conditioning voltage pulses, in accordance with some embodiments of the present disclosure.

FIGS. 7B and 7C illustrate exemplary effects of different numbers of pre-conditioning loops on the different memory units of FIG. 7A, in accordance with some embodiments of the present disclosure.

FIG. 8 illustrates histograms that show the statistical distribution of Iₒₙ of ferroelectric memory devices at different logical states with different pre-conditioning methods, in accordance with some embodiments of the present disclosure.

FIG. 9 is a block diagram of an electronic design automation (EDA) system, in accordance with some embodiments of the present disclosure.

FIG. 10 is a block diagram of an integrated circuit (IC) manufacturing system, and an IC manufacturing flow associated therewith, in accordance with some embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

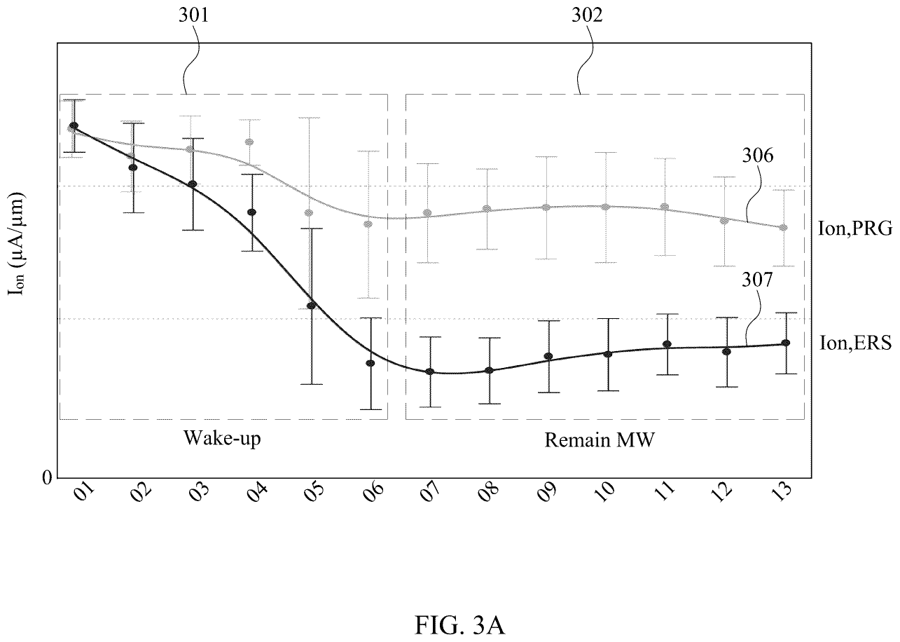

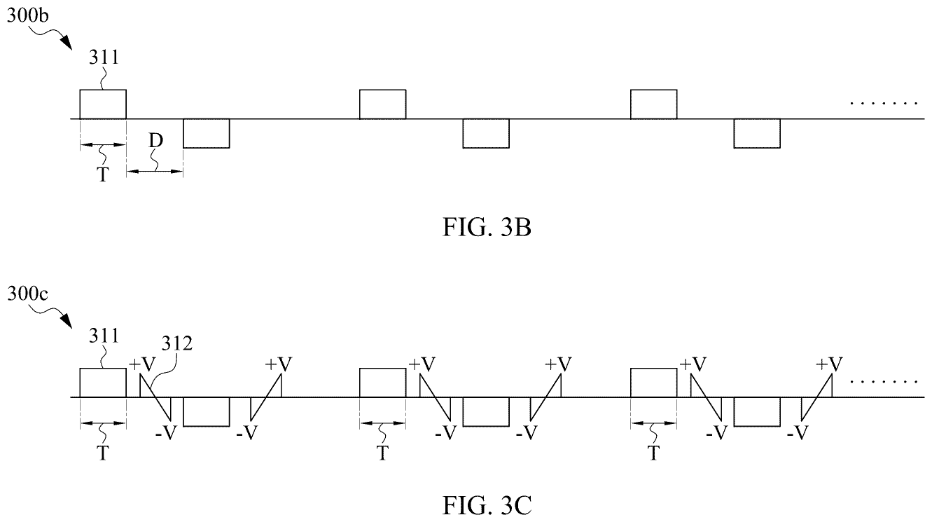

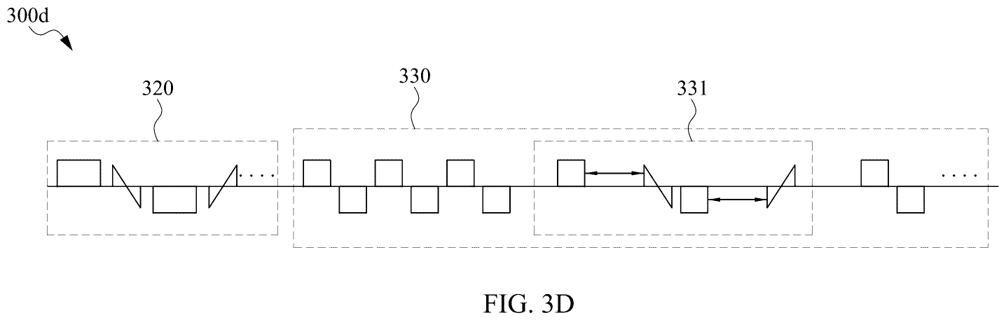

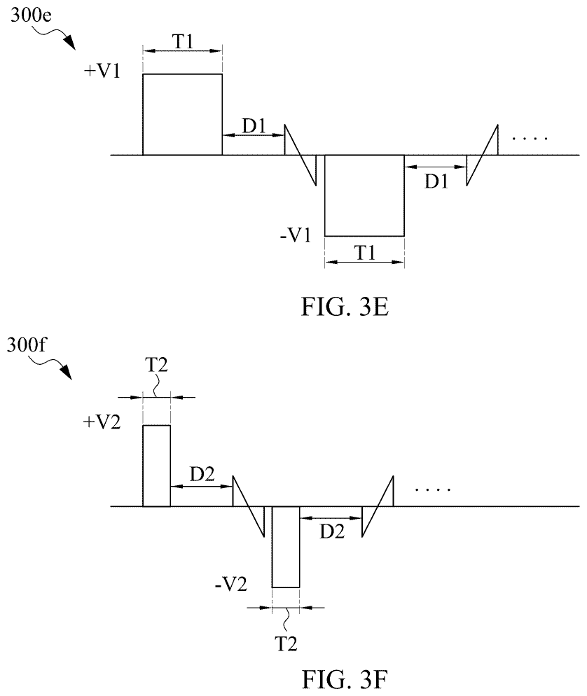

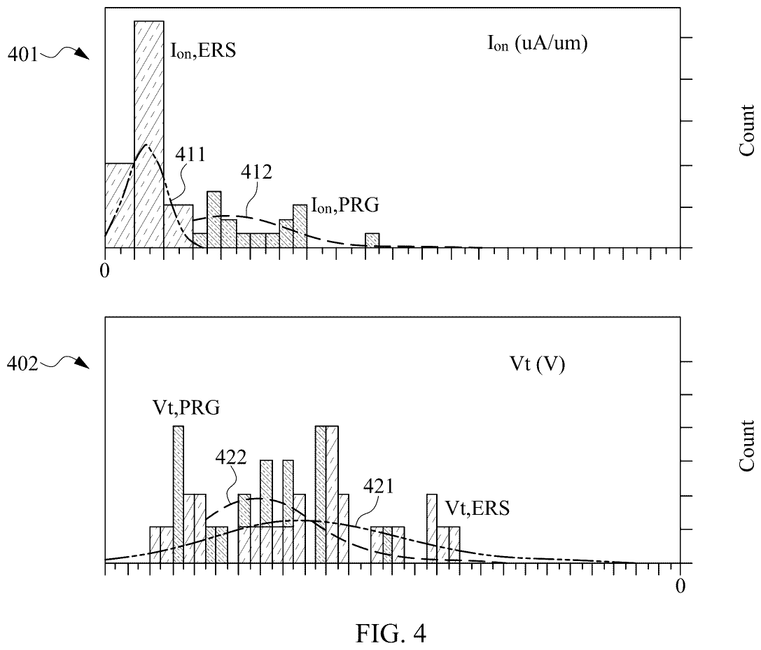

The figures herein follow a numbering convention in which the first digit or digits correspond to the drawing figure number and the remaining digits identify an element or component in the drawing. Similar elements or components between different figures may be identified by the use of similar digits. For example, 324 may reference element “24” in FIG. 3, and a similar element may be referenced as 424 in FIG. 4. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure, and should not be taken in a limiting sense.

Embodiments of the disclosure may be implemented in hardware, firmware, software, or any combination thereof. Embodiments of the disclosure may also be implemented as instructions stored on a tangible machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90° or at other orientations) and the spatially relative descriptors used herein may likewise be interpreted accordingly.

In the present disclosure, a structure or feature described as being “on” or “over” another structure or feature means and includes that the structure or feature is directly on top of, adjacent to, underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

In the present disclosure, the phrase “one of A, B and C” means “A, B and/or C” (A, B, C, A and B, A and C, B and C, or A, B and C), and does not mean one element from A, one element from B and one element from C, unless otherwise described.

In the present disclosure, “and/or” includes any and all combinations of one or more of the associated listed items.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., ±1%, ±2%, ±5%, ±10%, or ±15% of the value).

Further, it will be understood that when an element is referred to as being “connected to” or “coupled to” another element, it may be directly connected to or coupled to the other element, or intervening elements may be present.

As used herein, the term “electrode” may refer to an electrical conductor. It may be used as an electrical contact. An electrode may include a trace, wire, conductive line, conductive layer, or the like that provides a conductive path between different elements or components.

The embodiment(s) described, and references in the specification to “one embodiment,” “an embodiment,” “an exemplary embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

In the present disclosure, not every layer of a cell or a layout is depicted in the drawings. One of ordinary skill in the art should understand that the cell or the layout can include more layers to implement functionality of the cell and these layers are omitted merely for convenience of description.

In the present disclosure, terms such as “source/drain” and “source/drain region(s)” may refer to a source or a drain, individually or collectively, dependent upon the context.

The difference in one or more of the, e.g., electrical, properties of a memory device between two states (e.g., logical 0 and logical 1) is called “memory window” (MW). Fabricated memory devices usually have a performance threshold in terms of how wide their memory window is.

A ferroelectric material may maintain its polarization state even without continuing presence of external electric fields. Ferroelectric (FE) memory devices make use of this property to store information/states in a non-volatile manner. However, newly fabricated ferroelectric memory devices may have small a memory window. The newly fabricated ferroelectric memory devices may be “pre-conditioned” to increase the memory window to appropriate levels. The pre-conditioning operation may be referred to as “waking up” the ferroelectric memory devices.

One exemplary pre-conditioning method is to apply a signal, such as a (voltage) pulse train to the fabricated ferroelectric memory devices. The pulses may have a constant voltage. Each of the pulses in the pulse train may help increase the memory window. The pulse train may stop after the memory window has reached a performance threshold.

An integrated circuit may have numerous ferroelectric memory devices. In a comparative embodiment, the same pulse train is applied to all the ferroelectric memory devices in the integrated circuit. This, however, may not be able to take full account of the variation in the physical properties of different ferroelectric memory devices. For example, some ferroelectric memory devices may have insufficient memory window even after the pre-conditioning. It is possible to increase the strength of the pulse train by, for example, using a higher voltage. Too high a voltage, however, may adversely impact the endurance of the fabricated ferroelectric memory devices. Hence, the pre-conditioning method may be further optimized.

Embodiments of the present disclosure include adapting the strength of successive pulses of the pre-conditioning pulse train. The memory window of a ferroelectric memory device being pre-conditioned may be measured on the fly, and the pulse strength may be adapted in real-time, such as after each or some of the memory window measurements. These adaptive embodiments help to address the variation of the often large number of ferroelectric memory devices in an integrated circuit fabricated with modern technologies. The ability and flexibility to be adaptive also helps to protect the endurance (lifetime) of the fabricated ferroelectric memory devices by using pre-conditioning pulses that are sufficiently strong to wake them up but not strong enough to damage the ferroelectric properties of the ferroelectric materials in these memory devices.

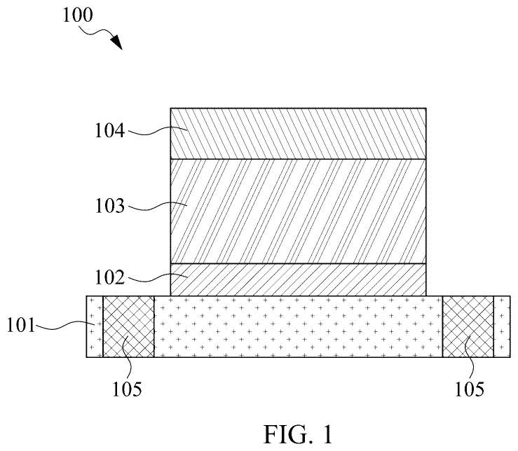

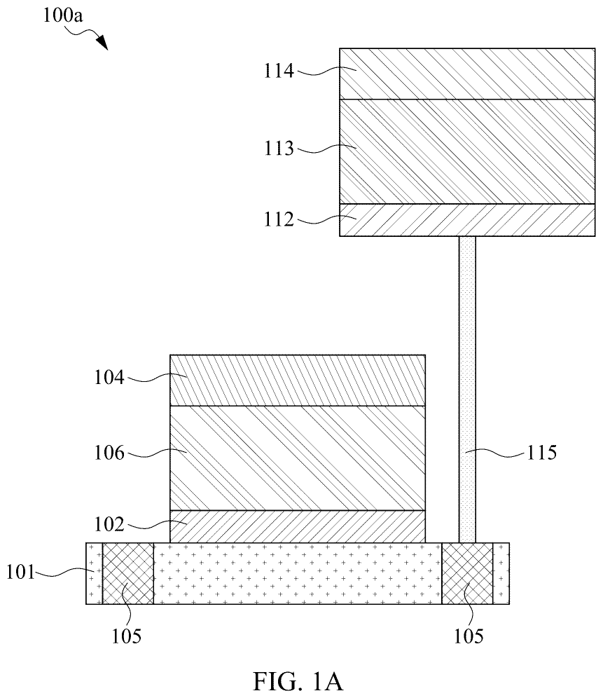

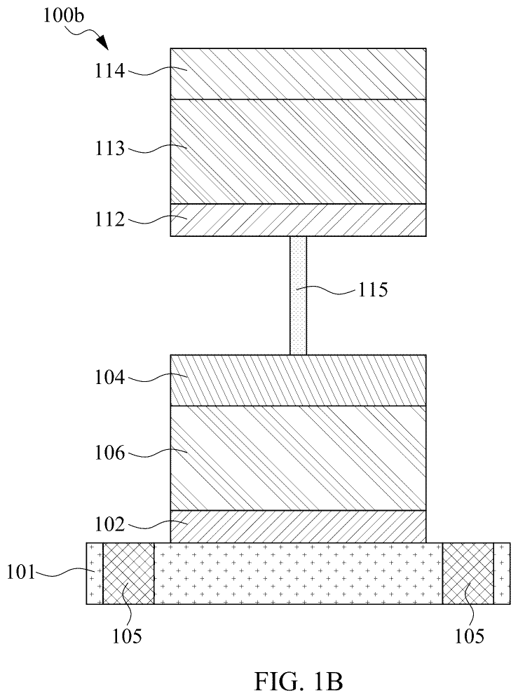

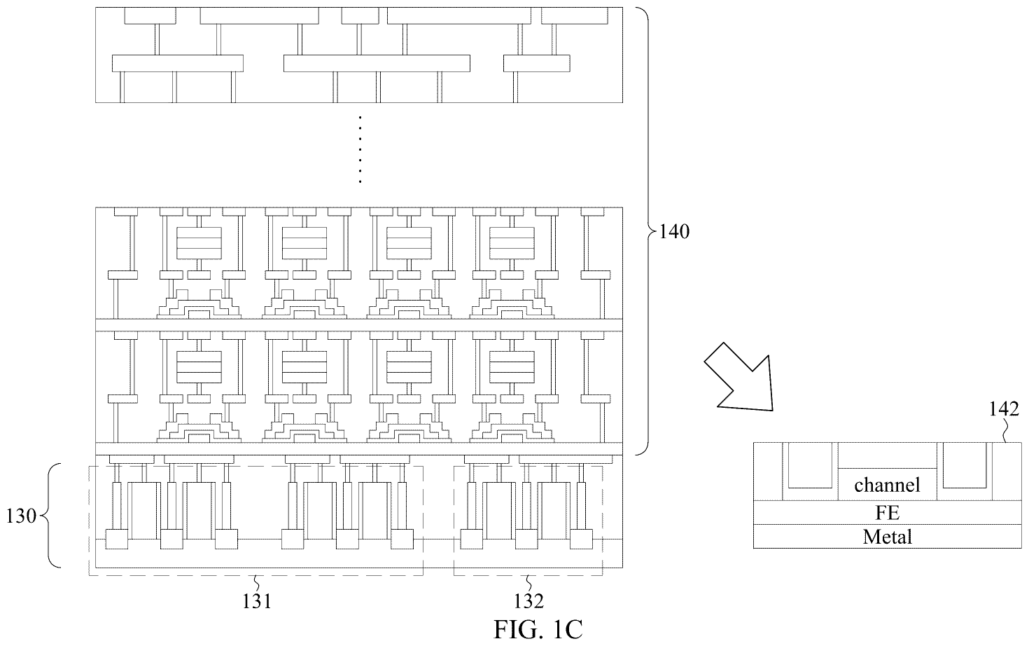

Refer to FIG. 1, which is a schematic cross sectional view of a ferroelectric device 100 in accordance with some embodiments of the present disclosure. The ferroelectric device 100 may be a semiconductor structure.

The ferroelectric device 100 includes a substrate 101, an insulator 102, a ferroelectric material 103 and an electrode 104. The structure of the ferroelectric device 100 may differ from a metal-oxide-semiconductor field-effect-transistor (MOSFET) for having the ferroelectric material 103 between the electrode 104 and the insulator 102. The structure of the ferroelectric device 100 may be referred to as a ferroelectric field-effect-transistor (FeFET).

The substrate 101 may include semiconductor materials, such as silicon. The silicon in the substrate 101 may be in various phases, such as poly-silicon and amorphous silicon. These are, however, merely exemplary and do not constitute limitation to the present disclosure. Other semiconductor materials are also possible. The substrate 101 may include p-type and/or n-type materials.

The substrate 101 may include one or more source/drain regions 105. The source/drain region 105 may include p-type and/or n-type materials. The source/drain region 105 may be formed by, for example, deposition and doping.

The insulator 102 may be, for example, oxides, such as silicon dioxide.

The ferroelectric material 103 may include hafnium (Hf), such as HfZrO, HfAIO, HfLaO, HfCeO, HfO, HfGdO, HfSiO. The ferroelectric material 103 may also include other appropriate ferroelectric materials.

The ferroelectric device 100 may be used as a memory device or memory unit, because the polarization state in the ferroelectric material 103 may changed in response to an application of an external electric field (“write”). The new polarization state may maintain even after the external electric field ceases to exist, making ferroelectric (FE) memory devices non-volatile.

The polarization state may affect the voltage-current characteristic of the ferroelectric memory device, thereby enabling the sensing of the polarization state (“read”). For example, in a FE memory device which can distinguish between two polarization states, different amount of currents may appear in response to a fixed amount of sensing (or read) voltage. For example, a larger amount of current may be generated in response to the application of the read voltage when the polarization state is in the first state than in the second state. The first state may correspond to logical 1, or called “programmed” state or “PRG” state; the second state may correspond to logical 0, or called “erased” state or “ERS” state.

FIGS. 1A, 1B and 1C are the schematic cross sectional views of several semiconductor structures in accordance with some embodiments of the present disclosure.

FIG. 1A illustrates a ferroelectric device 100a, which has a substrate 101, an insulator 102, a dielectric 106 (such as a high-K dielectric) and an electrode 104. The ferroelectric device 100a may also have a material stack including an electrode 112, a ferroelectric material 113 and an electrode 114. The material stack may be connected to (the source/drain region 105 of) the substrate 101 by an electrical interconnect 115.

FIG. 1B illustrates a ferroelectric device 100b. The ferroelectric device 100b differs from the ferroelectric device 100a in that the material stack (the ferroelectric material 113 and the electrodes 112 and 114) are connected to the electrode 104 instead of the substrate 101. Nevertheless, both ferroelectric devices 100a and 100b may be used to store information thanks to the presence of the ferroelectric material 113.

FIG. 1C illustrates a semiconductor structure according to other embodiments. The semiconductor structure shown here includes a front-end-of-line (FEOL) portion 130 and a back-end-of-line (BEOL) portion 140.

The FEOL portion 130 includes a region 131 that may include logic circuits and/or SRAM circuits. The FEOL portion 130 may also include a region 132 that may include circuits with various kinds of functions, such as peripheral, input/output (I/O) and analog circuits.

The BEOL portion 140 includes embedded memory units, such as one or more ferroelectric memory devices 141. An exemplary ferroelectric memory device 141 includes a (thin-film) transistor electrically coupled to a material stack including a ferroelectric material. The BEOL portion 140 may include other types of ferroelectric memory devices, such as the ferroelectric memory device 142 that includes a layer of conductive material, a layer of ferroelectric material, and a layer of (oxide) semiconductor material sandwiched between a pair of source/drain regions.

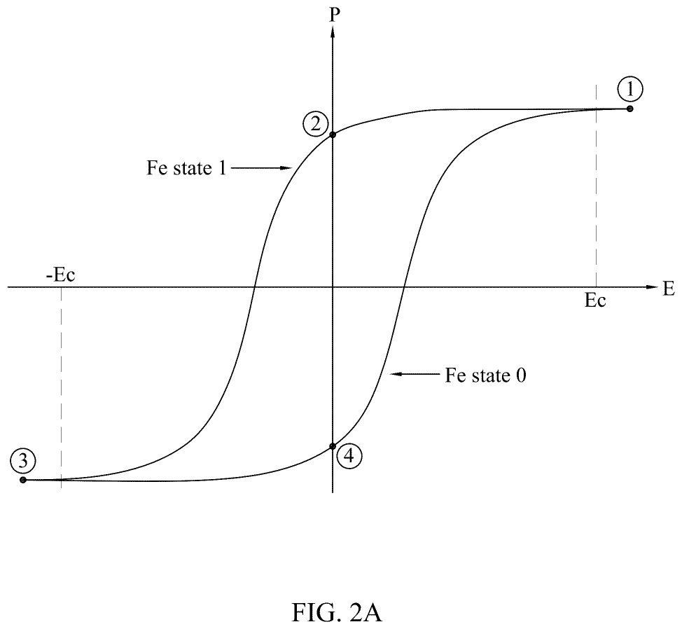

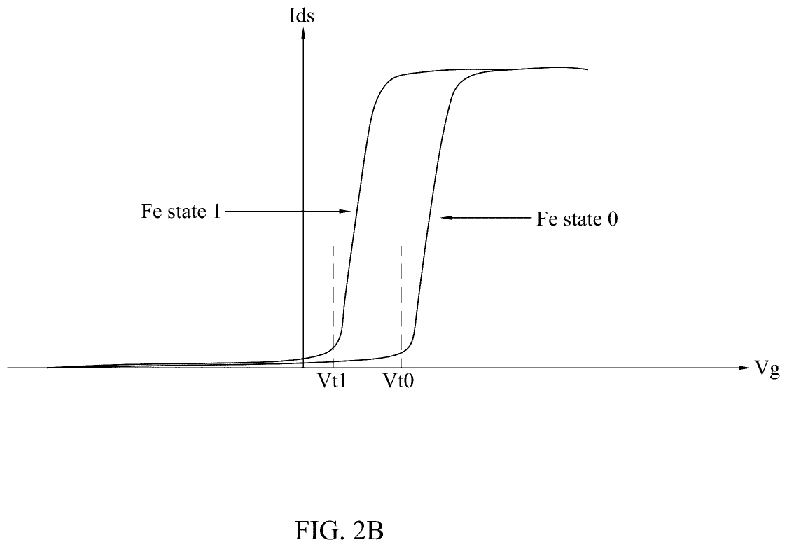

A ferroelectric material is a material in which the polarization P induced by an applied electrical field E shows a hysteresis curve as shown in FIG. 2A. The ferroelectric material may be an insulator. FIG. 2A shows four states when a varying electrical field is applied to a ferroelectric material. State 1 shown in FIG. 2A is a case for writing a logical 1, where the polarization P results from the E field is higher than a positive critical electrical field Ec. When the applied E field is removed, the polarization state remains as shown at state 2 in FIG. 2A, i.e. the logical 1 state. To write a logical 0, a negative E field lower than a negative critical field −Ec is applied, which reverses the induced polarity P resulting in state 3 shown in FIG. 2A. When the external E field is removed, the polarization state remains as shown at state 4 in FIG. 2A, i.e. the logical 0 state.

Refer back to the exemplary ferroelectric memory device 100 in FIG. 1. The polarization state of the ferroelectric material 103 may affect the level of the threshold voltage (Vₜ) of the ferroelectric device 100. FIG. 2B illustrates two Vₜ levels that may be exhibited by a ferroelectric memory device like the ferroelectric memory device 100. As shown in FIG. 2B, two distinct Vₜ values are established that correspond to the two states of the ferroelectric material 103. The Vₜ₁ level may correspond to logical 1 (or “PRG” state), and the Vₜ₀ level may correspond to the logical 0 state (or “ERS” state). The ability to store two different states makes this type of ferroelectric memory device capable of storing one bit of information. The (magnitude of the) difference between Vₜ₀ and Vₜ₁ may be viewed as a memory window metric. As another example, the threshold voltage associated with the PRG state may be indicated as V_{t,PRG} and that associated with the ERS state may be indicated as V_{t,ERS}.

Another memory window metric may be the amounts of current generated by a (ferroelectric) memory cell in the PRG and ERS states in response to an applied voltage; these amounts of currents may be indicated as I_{on,PRG} and I_{on,ERS}, respectively.

The difference in the threshold voltages or the response currents may be used to measure how wide the memory window (MW) is. The wider the memory window, the larger the difference between the two states, and therefore the more error margin there will be in distinguishing between the two states. The memory window is a performance metric of memory devices. The differences may be denoted by ΔVₜ (threshold voltage) or ΔI_{ON} (response current).

There may be a performance threshold (“spec”) for memory window that fabricated memory devices have to meet. The performance thresholds may vary depending on application requirements. Immediately after a ferroelectric memory device (ferroelectric memory unit) is fabricated, however, its memory window may be small. To make the memory window meet associated performance thresholds, a voltage pulse train may be applied to the just fabricated ferroelectric memory device to pre-condition the ferroelectric memory device, or to “wake it up.”

The voltage pulse train may include successive voltage pulses with alternating polarities. The duration of each pulse may vary. The duration between two successive pulses may also vary. The pulse shape may also vary. Characteristics of the pulse train may be affected by the properties of the ferroelectric materials used in the ferroelectric memory devices (such as the polycrystalline nature of the ferroelectric materials in use). After the application of the voltage pulse train, the memory window of fabricated ferroelectric memory cells may widen or enlarge. After the memory window is widened past the applicable performance threshold, the ferroelectric memory device may be considered as having been pre-conditioned or “woken up.”

FIG. 3A exemplarily illustrates the effect of the pre-conditioning (or “wake-up”) process on the memory window of an exemplary ferroelectric memory device, in accordance with some embodiments of the present disclosure. In this example, the memory window is measured by the amount of current Iₒₙ from a ferroelectric memory device in response to a (e.g., constant) sensing voltage. The current Iₒₙ is shown on the vertical axis.

The horizontal axis indicates different iterations of the application of the pre-conditioning pulse train. Different iterations may have different pulse widths. In the beginning, the pulse width may be narrow (say, in the range of tens of nanoseconds (ns)), and the response currents between the two states do not differ from each other significantly. In the second iteration, the pulse width may increase, and then the measured memory window could also widen. In subsequent iterations, the pulse width may further increase; the memory window continues to widen, and we may say that the ferroelectric memory device is being pre-conditioned or “woken up,” as indicated in the region 301 surrounded by a dashed-line box.

After several iterations, the pulse width start to decrease. The memory window, in contrast, stays approximately the same, as can be seen by the difference between the curve 306 (the current Iₒₙ when the ferroelectric memory device is at the PRG state) and the curve 307 (the current Iₒₙ when the ferroelectric memory device is at the ERS state) in the region 302. The pre-conditioning process may then terminate.

FIG. 3B illustrates an exemplary pulse train 300b for pre-conditioning, in accordance with some embodiments. The pulse train 300b may include successive pulses 311, each having duration T. Successive pulses 311 may be separated in time by the amount D. The amounts of T and D may vary. Successive pulses 311 may be of opposite polarities. Refer back to FIG. 2A: to push the ferroelectric material into different states, external electric fields with different polarities (plus or minus sign) are applied.

FIG. 3C illustrates an exemplary pulse train 300c for pre-conditioning, in accordance with some embodiments. In the pulse train 300c, (voltage) ramps 312 are introduced between successive pulses. The ramps 312 may be used for reading/sensing the ferroelectric memory devices being pre-conditioned.

FIG. 3D illustrates an exemplary pulse train 300d, in accordance with some embodiments. The pulse train 300d includes a pre-conditioning phase 320, which includes a pulse train similar to the pulse train 300c shown in FIG. 3C. The pulse train 300d includes an endurance cycling phase 330, in which the ferroelectric memory devices go through endurance cycling to test their durability (life time). Endurance cycling may be interspersed with reading phases 331 to check the memory operation and performance one or more times.

FIGS. 3E and 3F illustrates exemplary pulse trains 300e, 300f for pre-conditioning, in accordance with some embodiments. As can be seen in FIGS. 3E and 3F, the voltage pulses may of different magnitudes (V1 and V2) and/or different duration (T1 and T2). The time difference between the a voltage pulse and a ramp may also differ (D1 and D2). In some embodiments, V1 and V2 may be as low as 0.05V, and may be as high as 2.4V. Other values are also possible.

A ferroelectric memory (which may be fabricated on an integrated circuit) may include a plurality of ferroelectric memory devices (or “units” or “cells”). Each ferroelectric memory cell may have its own V_{t,PRG} and V_{t,ERS} (or its own I_{on,PRG} and I_{on,ERS}), and hence its own memory window (ΔVₜ or ΔI_{ON}). As such, the ferroelectric memory may exhibit a statistical distribution of different V_{t,PRG} and V_{t,ERS} (or I_{on,PRG} and I_{on,ERS}) values. These statistical distributions may be illustrated in histograms. In some examples, the statistical distributions of V_{t,PRG} and V_{t,ERS} (or I_{on,PRG} and I_{on,ERS}) values may be expressed as two bell-shaped curves with respective means (or peaks) and standard deviations (or spread or “waist” of the bell-shaped curves).

FIG. 4 illustrates histograms 401, 402 that show exemplary statistical distribution of Iₒₙ and Vₜ of a ferroelectric memory having a plurality of ferroelectric memory cells at different logical states, in accordance with some embodiments of the present disclosure. The bars indicate the number of ferroelectric memory cells having Iₒₙ and Vₜ in particular numerical ranges (bins) in different PRG and ERS states. The curves 411, 412 indicate the statistical distribution of I_{on,ERS} and I_{on,PRG}, respectively. The curves 421, 422 indicate the statistical distribution of V_{t,ERS} and V_{t,PRG} and, respectively.

In order to reduce reading or writing errors and increase memory reliability, it could be advantageous that the bell-shaped curves of V_{t,PRG} and V_{t,ERS} have little or no overlap. It could be advantageous to widen the separation between the peaks of the distributions of V_{t,PRG} and V_{t,ERS}. It could also be advantageous to reduce the spread of the distributions of V_{t,PRG} and V_{t,ERS}. It could also be advantageous to have more uniform values V_{t,PRG} and V_{t,ERS} across the memory cells in the same memory device.

As mentioned above, ferroelectric memory cells may be pre-conditioned by the application of a voltage pulse train. It is possible to increase the memory window by using stronger (e.g., higher voltages) and/or longer pulses during the pre-conditioning. However, voltages that are too strong and/or voltage pulses that are too long may undesirably impact the ferroelectric materials and adversely impact the durability (e.g., lowering endurance performance) of the ferroelectric memory cells.

It could be advantageous to increase the uniformity of performance across different memory cells. It could be advantageous to protect endurance performance. It could be advantageous to provide pre-conditioning that is customized for each memory cells to take into account of property variation among the memory cells, thereby optimizing memory cell performance, in a systematic and efficient manner. It could be advantageous to make endurance measurement more reliable.

The pre-conditioning voltage pulse train may be adaptive. In an example, successive pulses may have different voltages. In an example, successive pulses may have non-decreasing voltages. In an example, successive pulses may have increasing voltages. The voltages may keep increasing until the memory window of the memory cell reaches a threshold. The voltages may keep increasing until the durability of the memory cell could be negatively affected. In an example, the voltages is gradually increased in increments until a desirable memory performance is achieved, where the memory performance may be evaluated by the difference between the threshold voltages at different states and/or between the response currents at different states.

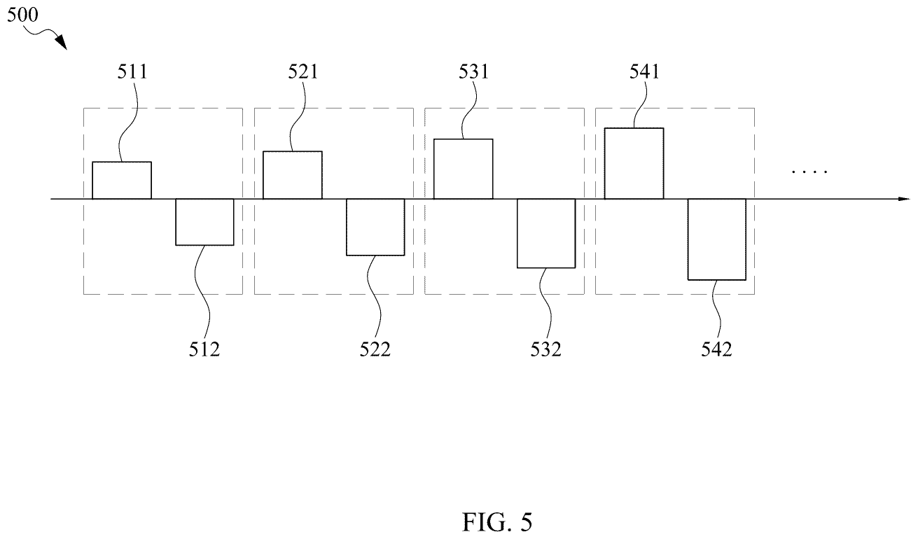

FIG. 5 illustrates a pulse train 500 (e.g., voltage pulse train), in accordance with some embodiments of the present disclosure. The pulse strength (e.g., pulse voltage) may be adaptive. For example, a pair of pulses 511, 512 may be followed by a pair of pulses 521, 522 with a higher voltage magnitude, which may in turn be followed by a pair of pulses 531, 532 with a higher voltage magnitude, which may in turn be followed by a pair of pulses 541, 542 with a higher voltage magnitude, and so on.

The memory window of the ferroelectric memory cell being pre-conditioned may be regularly measured. For example, the memory window may be measured after each pair of pulses. The voltage magnitude may change, depending on the measured memory window. The voltage pulse train shown in the embodiment of FIG. 5 may be called “incremental step pulse programming” (ISPP). It should be noted, however, that the voltage of the pulse trains of the present disclosure is not limited to monotonic increasing. Other adaptations are also included in the present disclosure. The manner in which the voltage magnitude may change based on the measured memory window in some embodiments may be further explained below.

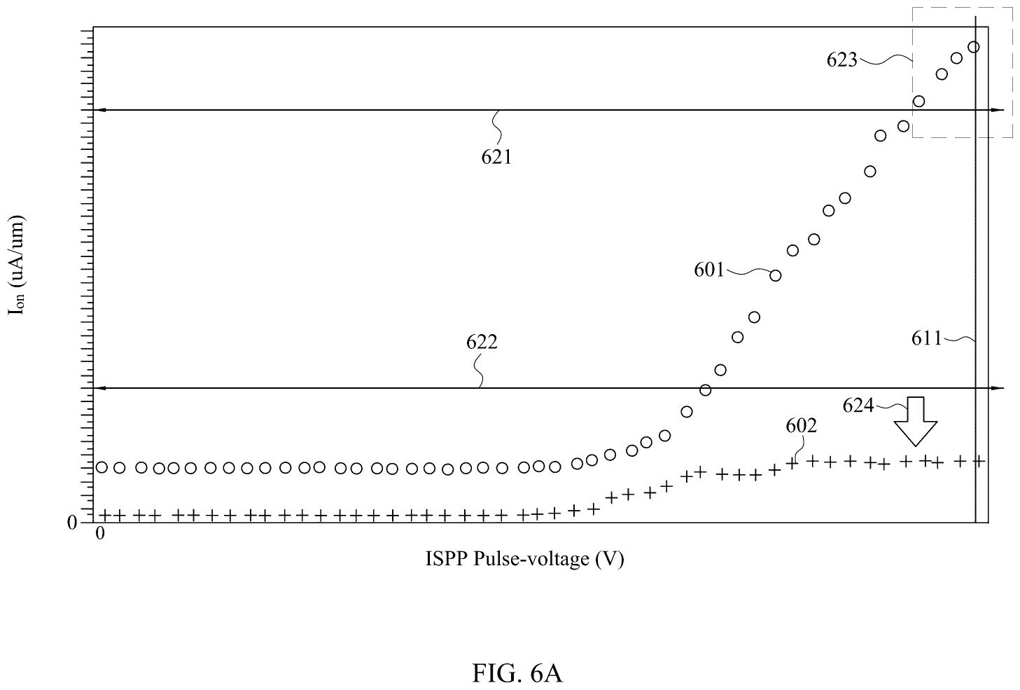

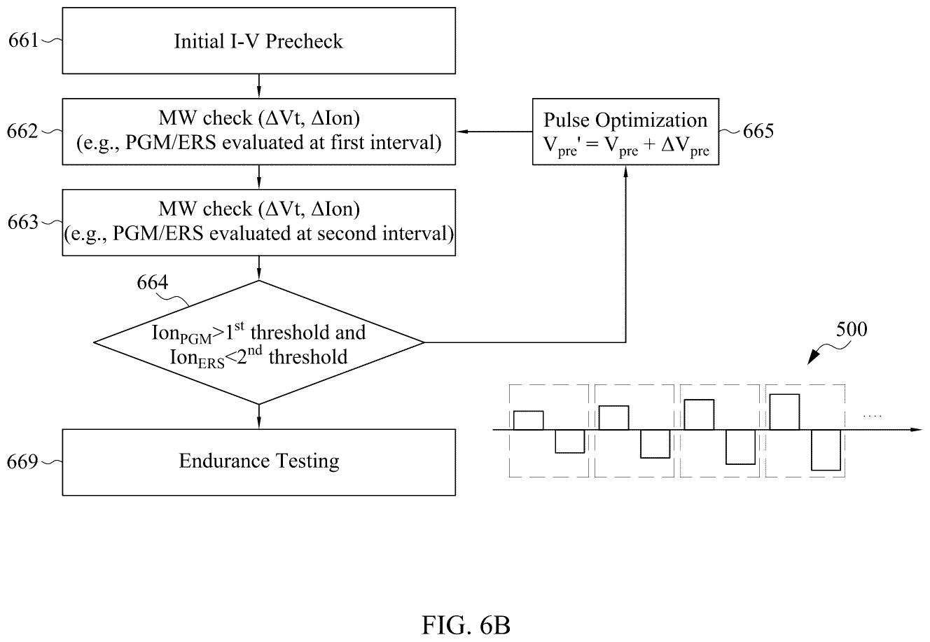

FIG. 6A illustrates exemplary effects on Iₒₙ at two different logical states with different amount of pulse voltages during pre-conditioning, in accordance with some embodiments of the present disclosure.

The chart in FIG. 6A illustrates how Iₒₙ (vertical axis) at different logical states changes with gradually increasing pulse voltage magnitude (horizontal axis). The curve 601 indicates the PRG state, and the curve 602 indicates the ERS state. The difference in height between curves 601, 602 can be seen as a measurement of the memory window.

From curve 601, it can be seen that I_{on,PRG} gradually increases, indicating the effect of the pre-conditioning process, which, in this embodiment, terminates when the pulse strength reaches the voltage level 611. In some embodiments, the voltage level 611 may be between 1.8V and 3.0V; between 2.0V and 2.8V; between 2.2V and 2.6V; or in other appropriate ranges.

In an embodiment, the voltage level 611 may be about 2.4V. The voltage level 611 may be chosen depending on device characteristics so that the pre-conditioning strength does not become excessive. The curve 602 indicates that the increase in I_{on,ERS} is limited. The limited increase in I_{on,ERS} is advantageous because too high an increase would actually reduce the memory window. This also shows an advantage of the embodiments of the methods of the present disclosure: the pulse strength can be adapted to be sufficiently strong to “open” the memory window, but not too strong to “close” it at the end.

To further illustrate the advantages of the embodiments of the present disclosure, the current level 621 and the current level 622 are indicated in the chart in FIG. 6A. The current level 621 and current level 622 indicate the level I_{on,PRG} and I_{on,ERS} reaches, respectively, after a comparative embodiment of pre-conditioning in which the pulse strength stays constant throughout the pre-conditioning process. In said comparative embodiment, the achieved memory window if the difference between the current level 621 and the current level 622, which is smaller than the difference between the curve 601 and the curve 602 at the voltage level 611. The box 623 indicates the increase in memory window on the part of I_{on,PRG}, and the arrow 624 indicates the increase in memory window on the part of I_{on,ERS} (the arrow 624, though pointing down, indicates an increase in memory window because the memory window can be measured from the vertical difference between the points on the curves 601 and 602).

FIG. 6B illustrates an exemplary flowchart that reflects a pre-conditioning process in accordance with some embodiments of the present disclosure. The illustrated process may be performed on individual memory cells, and may also be performed at larger units, such per-block, per-page, and per-die basis.

At step 661, ferroelectric memory devices (such as newly fabricated ferroelectric memory devices) may go through an initial check of their current-voltage characteristics.

At step 662, the memory window of the ferroelectric memory devices is measured. The memory window may be measured by looking at, for example, the difference in threshold voltage Vₜ or response current Iₒₙ between different logic states. The measurement may be performed at a first interval. The first interval may be in the order of microseconds. In some embodiments, the first interval may be between 800 ms and 1000 ms; between 600 ms and 800 ms; between 400 ms and 600 ms; between 200 ms and 400 ms; between 50 ms and 200 ms; or in other appropriate ranges. In an embodiment, the first interval may be about 100 ms. At step 663, the memory window may be measured again. The measurement may be performed at a second interval. The second interval may differ from the first interval. In some embodiments, the second interval may be shorter than the first interval (i.e., more frequent measurements). In some embodiments, the second interval may be in the order of nanoseconds. In some embodiments, the second interval may be between 800 ns and 1000 ns; between 600 ns and 800 ns; between 400 ns and 600 ns; between 200 ns and 400 ns; between 50 ns and 200 ns; or in other appropriate ranges. In an embodiment, the first interval may be about 100 ns.

At step 664, the memory window may be measured, and the response from the two states (such as I_{on,PRG} and I_{on,ERS}) may be recorded. If the measured memory window meets a performance threshold or criteria, then the pre-conditioning process terminates and the memory devices will go through endurance testing (at step 669). If the performance threshold is not met, then the pulse strength is being adapted at step 665.

The performance threshold used in step 664 may include a number for ΔVₜ and/or ΔIₒₙ. The performance threshold may alternatively or additionally include separate threshold levels for responses from respective logic states. For example, the performance threshold may include a minimum current level that I_{on,PRG} is required to meet, and/or a maximum current level that I_{on,ERS} is required to not breach. The minimum I_{on,PRG} may be in the range of 10 uA/um to 500 uA/um, 30 uA/um to 300 uA/um, 50 uA to 150 uA/um, or other appropriate ranges. In an embodiment, an exemplary minimum I_{on,PRG} is about 100 uA/um. The maximum I_{on,ERS} may be in the range of 5 uA/um to 300 uA/um, 10 uA/um to 150 uA/um, 20 uA to 80 uA/um, or other appropriate ranges. In an embodiment, an exemplary maximum I_{on,ERS} is about 55 uA/um.

The pulse adaptation is performed at step 665. The adaptation may be an adjustment to the pulse strength (voltage magnitude) to the next pulse or the next pair of pulses with opposite polarities. The pulse train 500, shown in FIG. 5, is reproduced here to help illustrate step 665. Vₚᵣₑ is the pulse strength in the current adaptation iteration, ΔVₚᵣₑ is the amount of adjustment to the pulse strength, and Vₚᵣₑ′ is the adjusted pulse strength to be used in the next iteration. The adjustment amount ΔVₚᵣₑ may be fixed or variable. For example, when the measured memory window is small (which may indicate the beginning or early stage of the pre-conditioning), ΔVₚᵣₑ may be set to a larger value to increase the pre-conditioning strength more rapidly/aggressively. In contrast, when the measured memory window becomes larger (which may indicate the pre-conditioning is no longer in the beginning phase), ΔVₚᵣₑ may be set to a smaller value to increase the pre-conditioning strength more slowly/less aggressively. In some embodiments, ΔVₚᵣₑ may alternatively or additionally vary depending on how fast the measured memory window changes in response to a given amount of ΔVₚᵣₑ. If the measured memory window changes rapidly (i.e., producing a strong response) to a given amount of ΔVₚᵣₑ, then ΔVₚᵣₑ may decrease to allow finer control of how fast the memory window may change. After the adaptation/optimization, the memory window of the memory devices is checked again at step 662. One or more iterations may be performed before the pre-conditioning process terminates.

The voltage magnitude adjustment may have different scales. An exemplary scale is 0.05V; that is, the magnitude is adjusted by 0.05V at a time. Other scales are also possible, such as 0.01V, 0.02V, 0.03V, 0.04V, 0.06V, 0.07V, 0.08V, 0.09V, 0.1V, 0.15V, 0.2V, 0.25V, 0.3V, 0.35V, 0.4V, 0.45V, 0.5V, 0.6V, 0.7V, 0.8V, 0.9V, 1.0V and other appropriate values.

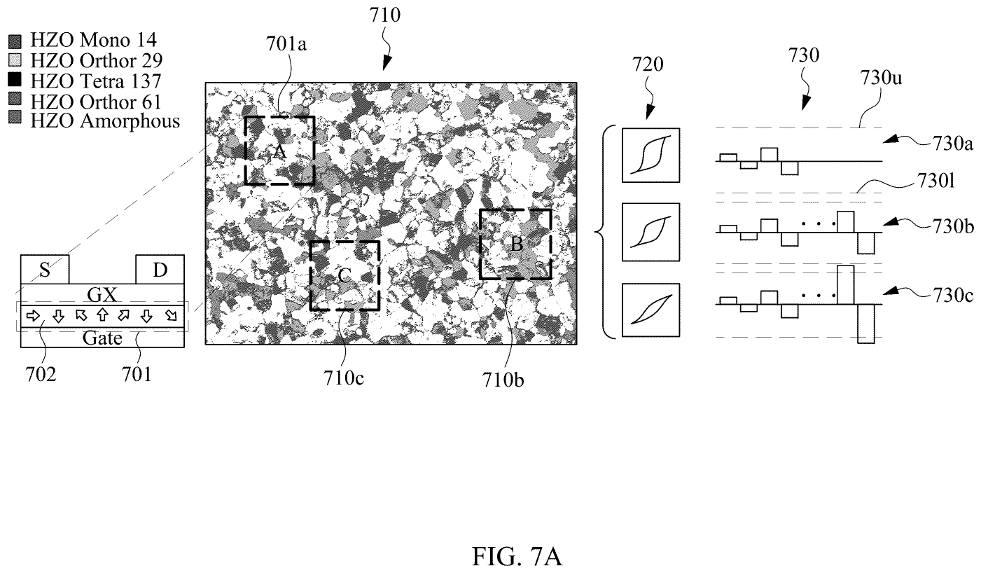

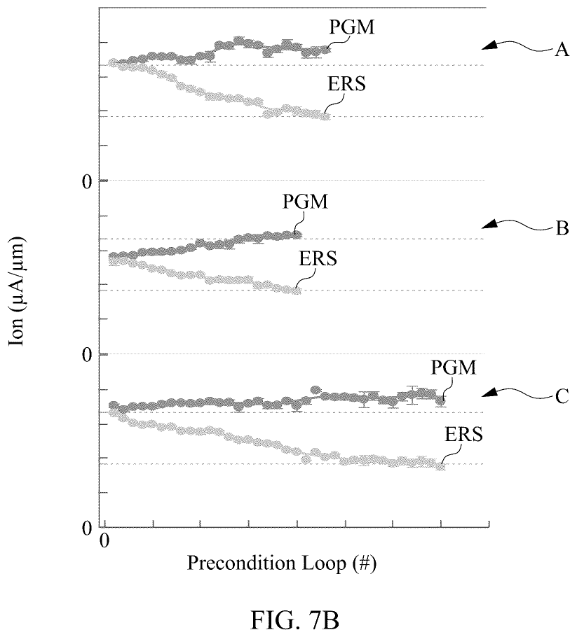

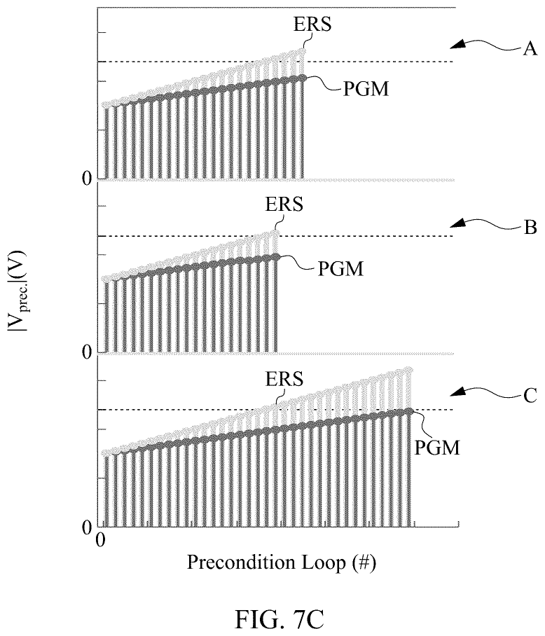

FIG. 7 illustrates a picture 710 of a layer of ferroelectric material of several different memory units (examples indicated in regions 710a, 710b, 710c), and exemplary associated hysteresis curves (in graph 720) and pre-conditioning voltage pulses (see graph 730), in accordance with some embodiments of the present disclosure.

Ferroelectric materials may include hafnium, such as HZO. Ferroelectric materials may have different material properties and structures. Significant variation may exhibit across different regions of the same layer of ferroelectric materials. The variation may be caused by factors such as limited domain numbers and intrinsic stochasticity (randomness) of individual domain switching. The variation may contribute to device-to-device variation in the performance of ferroelectric memory devices. The performance may be dominated by a few grains. The variation of material properties is exemplarily illustrated in picture 710, which shows a layer of hafnium-zirconium oxide (HZO) with random distribution of different HZO phases, such as monoclinic (mono), orthorhombic (ortho), tetra and amorphous.

Each of the regions 710a, 710b, 710c may indicate the ferroelectric materials in one memory device (cell). For example, region 710a may correspond to the ferroelectric material 701 in a memory cell with source/drain regions and associated insulators. The various arrows 702 indicate differences in polarization amounts and directions across the ferroelectric material 701. Such differences contribute to different hysteresis curves of the regions 710a, 710b, 710c, as indicated in graph 720.

In comparative embodiments, the variation may be addressed by manufacturing process control, such as controlling the number of domains and improving domain uniformity. In contrast, the embodiments of the pre-conditioning algorithm of the present disclosure may help improve device performance uniformity not by way of manufacturing process control but through the control of external signals applied to the memory devices. Performance uniformity is improved by the ability to customize the pre-conditioning signals for individual memory devices.

The customizability is illustrated in graph 730, which shows pulse trains 730a, 730b, 730c respectively for pre-conditioning the memory devices corresponding to regions 710a, 710b, 710c (also denoted as device A, B, C in picture 710 and graph 720).

As indicated in graph 720, the hysteresis curve of device A is “wide,” which may indicate more desirable performance characteristic. As such, the pre-conditioning pulse train 730a can terminate early with modest pulse strength. The hysteresis curve of device B is “narrower” or “has a smaller opening,” which may indicate more desirable performance characteristic. As such, the pre-conditioning pulse train 730b is longer than pulse train 730a and terminates at larger strength. Similarly, the pulse train 730c is adapted for the particular property (hysteresis curve) of device C.

In the comparative embodiment, the pre-conditioning pulse strength is constant and indicated by voltage levels 730u (“upper”) and 7301 (“lower”). The constant pulse strength would be less ideal in accommodating to variation across regions 710a, 710b, 710c. The constant pre-conditioning strength may be too large for device A, and insufficient for device C. In embodiments of the present disclosure, the customizability well accommodates to the device-to-device variation.

FIG. 7B illustrates another advantage of the customizability of the embodiments of the present disclosure, in that the length of the pre-conditioning process can be customized: shorter for devices with more desirable physical characteristics (such as device A), and longer for devices with less desirable physical characteristics (such as device C). It is worth noting that increasing the pre-conditioning strength may help reduce the pre-conditioning time; for example, it takes fewer loops to pre-condition device B than device A.

FIG. 7C illustrates other advantages of the customizability of the embodiments of the present disclosure. FIG. 7C not only shows that the length of the pre-conditioning process can be customized, but also that the pre-conditioning strength can be customized: stronger for those that need the strength (such as device C).

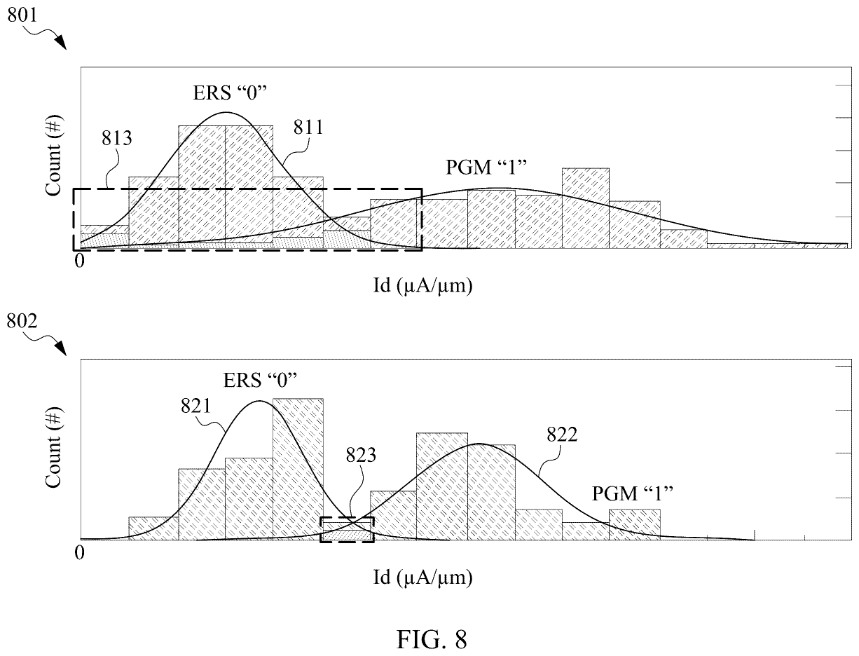

FIG. 8 illustrates another advantage of the customizability of the embodiments of the present disclosure.

Histograms 801, 802 show the statistical distribution of Iₒₙ of ferroelectric memory devices at different logical states with different pre-conditioning processes. More specifically, histogram 801 indicates the statistical result of a comparative pre-conditioning process where the pre-conditioning pulse is not customizable; and histogram 802 indicates the statistical result of the pre-conditioning process according to embodiments of the present disclosure where the pre-conditioning pulse is customizable.

In histogram 801, curves 811, 812 illustrate the distribution of the amount of conducting currents at the ERS (logical 0) and PRG states (logical 1), respectively. The curves 811 and 812 have overlap, as shown by box 813. In contrast, curves 821, 822 have smaller overlap, as indicated by box 823, which is smaller than box 813. The reduction in overlap helps improve memory performance.

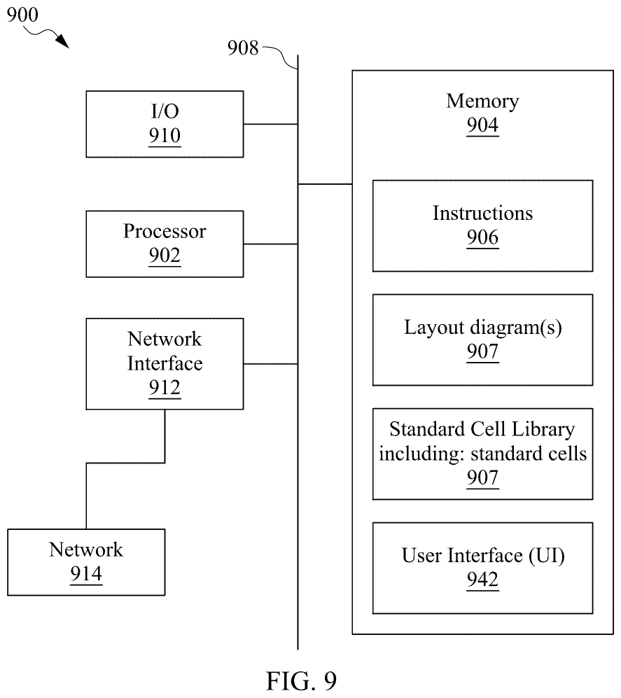

FIG. 9 is a block diagram of an electronic design automation (EDA) system 900, in accordance with some embodiments.

In some embodiments, EDA system 900 includes an APR system. Methods described herein of generating PG layout diagrams, in accordance with one or more embodiments, are implementable, for example, using EDA system 900, in accordance with some embodiments.

In some embodiments, EDA system 900 is a general purpose computing device including a hardware processor 902 and a non-transitory, computer-readable storage medium 904. Storage medium 904, amongst other things, is encoded with, i.e., stores, computer program code 906, i.e., a set of executable instructions. Execution of instructions 906 by hardware processor 902 represents (at least in part) an EDA tool which implements a portion or all of, e.g., the methods described herein in accordance with one or more (hereinafter, the noted processes and/or methods).

Processor 902 is electrically coupled to computer-readable storage medium 904 via a bus 908. Processor 902 is also electrically coupled to an I/O interface 910 by bus 908. A network interface 912 is also electrically connected to processor 902 via bus 908. Network interface 912 is connected to a network 914, so that processor 902 and computer-readable storage medium 904 are capable of connecting to external elements via network 914. Processor 902 is configured to execute computer program code 906 encoded in computer-readable storage medium 904 in order to cause system 900 to be usable for performing a portion or all of the noted processes and/or methods. In one or more embodiments, processor 902 is a central processing unit (CPU), a multi-processor, a distributed processing system, an application specific integrated circuit (ASIC), and/or a suitable processing unit.

In one or more embodiments, computer-readable storage medium 904 is an electronic, magnetic, optical, electromagnetic, infrared, and/or a semiconductor system (or apparatus or device). For example, computer-readable storage medium 904 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 904 includes a compact disk-read only memory (CD-ROM), a compact disk-read/write (CD-R/W), and/or a digital video disc (DVD).

In one or more embodiments, storage medium 904 stores computer program code 906 configured to cause system 900 (where such execution represents (at least in part) the EDA tool) to be usable for performing a portion or all of the noted processes and/or methods. In one or more embodiments, storage medium 904 also stores information which facilitates performing a portion or all of the noted processes and/or methods. In one or more embodiments, storage medium 904 stores library 907 of standard cells including such standard cells as disclosed herein.

EDA system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 902.

EDA system 900 also includes network interface 912 coupled to processor 902. Network interface 912 allows system 900 to communicate with network 914, to which one or more other computer systems are connected. Network interface 912 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 900.

System 900 is configured to receive information through I/O interface 910. The information received through I/O interface 910 includes one or more of instructions, data, design rules, libraries of standard cells, and/or other parameters for processing by processor 902. The information is transferred to processor 902 via bus 908. EDA system 900 is configured to receive information related to a UI through I/O interface 910. The information is stored in computer-readable medium 904 as user interface (UI) 942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 900. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

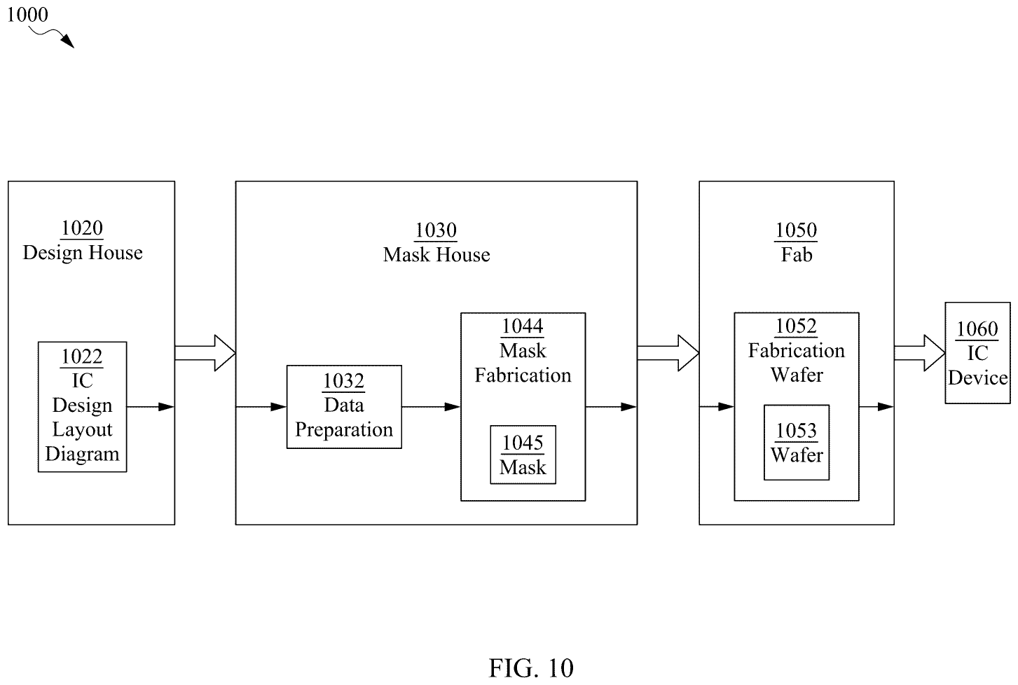

FIG. 10 is a block diagram of an integrated circuit (IC) manufacturing system 1000, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1000.

In FIG. 10, IC manufacturing system 1000 includes entities, such as a design house 1020, a mask house 1030, and an IC manufacturer/fabricator (“fab”) 1050, that interact with one another in the design, development, and manufacturing cycles and/or services related to manufacturing an IC device 1060. The entities in system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1020, mask house 1030, and IC fab 1050 is owned by a single larger company. In some embodiments, two or more of design house 1020, mask house 1030, and IC fab 1050 coexist in a common facility and use common resources.

Design house (or design team) 1020 generates an IC design layout diagram 1022. IC design layout diagram 1022 includes various geometrical patterns designed for an IC device 1060. The geometrical patterns correspond to patterns of metal, oxide, or semiconductor layers that make up the various components of IC device 1060 to be fabricated. The various layers combine to form various IC features. For example, a portion of IC design layout diagram 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1020 implements a proper design procedure to form IC design layout diagram 1022. The design procedure includes one or more of logic design, physical design or place and route. IC design layout diagram 1022 is presented in one or more data files having information of the geometrical patterns. For example, IC design layout diagram 1022 can be expressed in a GDSII file format or DFII file format.

Mask house 1030 includes data preparation 1032 and mask fabrication 1044. Mask house 1030 uses IC design layout diagram 1022 to manufacture one or more masks 1045 to be used for fabricating the various layers of IC device 1060 according to IC design layout diagram 1022. Mask house 1030 performs mask data preparation 1032, where IC design layout diagram 1022 is translated into a representative data file (“RDF”). Mask data preparation 1032 provides the RDF to mask fabrication 1044. Mask fabrication 1044 includes a mask writer. A mask writer converts the RDF to an image on a substrate, such as a mask (reticle) 1045 or a semiconductor wafer 1053. The design layout diagram 1022 is manipulated by mask data preparation 1032 to comply with particular characteristics of the mask writer and/or requirements of IC fab 1050. In FIG. 10, mask data preparation 1032 and mask fabrication 1044 are illustrated as separate elements. In some embodiments, mask data preparation 1032 and mask fabrication 1044 can be collectively referred to as mask data preparation.

In some embodiments, mask data preparation 1032 includes optical proximity correction (OPC) which uses lithography enhancement techniques to compensate for image errors, such as those that can arise from diffraction, interference, other process effects and the like. OPC adjusts IC design layout diagram 1022. In some embodiments, mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1032 includes a mask rule checker (MRC) that checks the IC design layout diagram 1022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1022 to compensate for limitations during mask fabrication 1044, which may undo part of the modifications performed by OPC in order to meet mask creation rules.

In some embodiments, mask data preparation 1032 includes lithography process checking (LPC) that simulates processing that will be implemented by IC fab 1050 to fabricate IC device 1060. LPC simulates this processing based on IC design layout diagram 1022 to create a simulated manufactured device, such as IC device 1060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1022.

It should be understood that the above description of mask data preparation 1032 has been simplified for the purposes of clarity. In some embodiments, data preparation 1032 includes additional features such as a logic operation (LOP) to modify the IC design layout diagram 1022 according to manufacturing rules. Additionally, the processes applied to IC design layout diagram 1022 during data preparation 1032 may be executed in a variety of different orders.

After mask data preparation 1032 and during mask fabrication 1044, a mask 1045 or a group of masks 1045 are fabricated based on the modified IC design layout diagram 1022. In some embodiments, mask fabrication 1044 includes performing one or more lithographic exposures based on IC design layout diagram 1022. In some embodiments, an electron-beam (e-beam) or a mechanism of multiple e-beams is used to form a pattern on a mask (photomask or reticle) 1045 based on the modified IC design layout diagram 1022. Mask 1045 can be formed in various technologies. In some embodiments, mask 1045 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1045 includes a transparent substrate (e.g., fused quartz) and an opaque material (e.g., chromium) coated in the opaque regions of the binary mask. In another example, mask 1045 is formed using a phase shift technology. In a phase shift mask (PSM) version of mask 1045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1044 is used in a variety of processes. For example, such a mask(s) is used in an ion implantation process to form various doped regions in semiconductor wafer 1053, in an etching process to form various etching regions in semiconductor wafer 1053, and/or in other suitable processes.

IC fab 1050 includes wafer fabrication 1052. IC fab 1050 is an IC fabrication business that includes one or more manufacturing facilities for the fabrication of a variety of different IC products. In some embodiments, IC Fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1050 uses mask(s) 1045 fabricated by mask house 1030 to fabricate IC device 1060. Thus, IC fab 1050 at least indirectly uses IC design layout diagram 1022 to fabricate IC device 1060. In some embodiments, semiconductor wafer 1053 is fabricated by IC fab 1050 using mask(s) 1045 to form IC device 1060. In some embodiments, the IC fabrication includes performing one or more lithographic exposures based at least indirectly on IC design layout diagram 1022. Semiconductor wafer 1053 includes a silicon substrate or other proper substrate having material layers formed thereon. Semiconductor wafer 1053 further includes one or more of various doped regions, dielectric features, multilevel interconnects, and the like (formed at subsequent manufacturing steps).

In sum, adaptive pre-conditioning processes help improve performance uniformity of ferroelectric memory devices, and may also protect device endurance by using strong pre-conditioning where warranted.

It will be understood that not all advantages have been necessarily discussed herein, no particular advantage is required for all embodiments or examples, and other embodiments or examples may offer different advantages.

According to an aspect of the present disclosure, a method is provided. The method includes applying a first pulse to a ferroelectric memory device, measuring a memory window metric of the ferroelectric memory device, and applying a second pulse to the ferroelectric memory device. The first pulse may have a first voltage magnitude. The second pulse may have a second voltage magnitude. The second voltage magnitude may be determined based at least in part on the measured memory window metric.

According to an aspect of the present disclosure, a non-transitory computer-readable medium is provided. The non-transitory computer-readable medium stores program instructions, which, when executed by a processor operatively coupled to the non-transitory computer-readable medium, cause the processor to perform a method. The method includes applying a first pulse to a ferroelectric memory device, measuring a memory window metric of the ferroelectric memory device, and applying a second pulse to the ferroelectric memory device. The first pulse may have a first voltage magnitude. The second pulse may have a second voltage magnitude. The second voltage magnitude may be determined based at least in part on the measured memory window metric.

In some examples, the second voltage magnitude may be different from the first voltage magnitude; in such examples, the second voltage magnitude may be larger than the first voltage magnitude.

In some examples, the first pulse may include a first sub-pulse of a first polarity and a second sub-pulse of a second polarity opposite the first polarity; in such examples, the second pulse may include a third sub-pulse of the first polarity and a fourth sub-pulse of the second polarity.

In some examples, the method may include iteratively measuring the memory window metric of the ferroelectric memory device and applying a subsequent pulse to the ferroelectric memory device, and the subsequent pulse may have a subsequent voltage magnitude determined based at least in part on the measured memory window metric. In these examples, the step of measuring the memory window metric and the step of applying the subsequent pulse to the ferroelectric memory device may be iteratively performed until the measured memory window metric reaches a threshold. In some examples, the method may include, in response to the measured memory window metric not reaching the threshold, changing the subsequent voltage magnitude of the subsequent pulse in the next iteration; in these examples, changing the subsequent voltage magnitude of the subsequent pulse in the next iteration may include increasing the subsequent voltage magnitude of the subsequent pulse in the next iteration.

In some examples, the threshold may include a first current amount and a second current amount; in these examples, the first current amount is larger than the second current amount. In some examples, the first current amount may be associated with a minimum amount of current associated with a first logic state of the ferroelectric memory device, wherein the first logic state may be a programmed state of the ferroelectric memory device. In some examples, the second current amount may be associated with a maximum amount of current associated with a second logic state of the ferroelectric memory device, wherein the second logic state may be an erased state of the ferroelectric memory device.

In some examples, the threshold may include a first voltage level and a second voltage level; in these examples, the first voltage level may be lower than the second voltage level. In some examples, the first voltage level and the second voltage level may be a first threshold voltage level associated with a first logic state of the ferroelectric memory device and a second threshold voltage level associated with a second logic state of the ferroelectric memory device, respectively. In these examples, the first logic state may be a programmed state of the ferroelectric memory device, or the second logic state may be an erased state of the ferroelectric memory device.

In some examples, the memory window metric may include a difference between a first amount of current generated by the ferroelectric memory device in a first logic state in response to a reading voltage and a second amount of current generated by the ferroelectric memory device in a second logic state in response to the reading voltage.

In some examples, the memory window metric may include a difference between a first threshold voltage associated with the ferroelectric memory device in a first logic state and a second threshold voltage associated with the ferroelectric memory device in a second logic state.

According to an aspect of the present disclosure, a method is provided. The method includes adapting voltage magnitudes of pulses of a pulse train. The pulse train is applied to a ferroelectric memory device. The pulse train may be applied in response to respective memory window metrics measured from the ferroelectric memory device. The measurement may take place after each of the applied pulses. The application of the pulse train may continue until the measured memory window metric reaches a threshold.

In some examples, the ferroelectric memory device may be a ferroelectric field-effect transistor (FeFET); in these examples, the FeFET may include a semiconductor material; an insulator vertically adjacent the semiconductor material; a ferroelectric material vertically adjacent the insulator; and an electrode vertically adjacent the ferroelectric material. In some examples, the pulses may be applied to the electrode, and the semiconductor material may be grounded when the pulses are applied.

In some examples, the ferroelectric memory device may be a ferroelectric random-access memory (FeRAM). In some examples, the ferroelectric memory device may be situated in a front-end-of-line (FEOL) portion of a semiconductor structure. In some examples, the ferroelectric memory device may be situated in a back-end-of-line (BEOL) portion of a semiconductor structure. In some examples, the ferroelectric memory device may include a hafnium-based ferroelectric material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
applying a first pulse to a ferroelectric memory device, wherein the first pulse has a first voltage magnitude;
measuring a memory window metric of the ferroelectric memory device;
applying a second pulse to the ferroelectric memory device, wherein the second pulse has a second voltage magnitude, wherein the second voltage magnitude is determined based at least in part on the measured memory window metric.

2. The method of claim 1, wherein the second voltage magnitude is different from the first voltage magnitude.

3. The method of claim 2, wherein the second voltage magnitude is larger than the first voltage magnitude.

4. The method of claim 1, wherein the first pulse comprises a first sub-pulse of a first polarity and a second sub-pulse of a second polarity opposite the first polarity.

5. The method of claim 1, further comprising iteratively measuring the memory window metric of the ferroelectric memory device and applying a subsequent pulse to the ferroelectric memory device, wherein the subsequent pulse has a subsequent voltage magnitude determined based at least in part on the measured memory window metric.

6. The method of claim 5, wherein the step of measuring the memory window metric and the step of applying the subsequent pulse to the ferroelectric memory device are iteratively performed until the measured memory window metric reaches a threshold.

7. The method of claim 6, further comprising:
in response to the measured memory window metric not reaching the threshold, changing the subsequent voltage magnitude of the subsequent pulse in the next iteration.

8. The method of claim 1, further comprising: applying an endurance cycling pulse train to the ferroelectric memory device.

9. The method of claim 1, further comprising applying a reading pulse train and an endurance cycling pulse train to the ferroelectric memory device, wherein the endurance cycling pulse train is interspersed with the reading pulse train.

10. A non-transitory computer-readable medium storing program instructions, which, when executed by a processor operatively coupled to the non-transitory computer-readable medium, cause the processor to perform a method comprising:
applying a first pulse to a ferroelectric memory device, wherein the first pulse has a first voltage magnitude;
measuring a memory window metric of the ferroelectric memory device;
applying a second pulse to the ferroelectric memory device, wherein the second pulse has a second voltage magnitude, wherein the second voltage magnitude is determined based at least in part on the measured memory window metric.

11. The non-transitory computer-readable medium of claim 10, wherein the second voltage magnitude is different from the first voltage magnitude.

12. The non-transitory computer-readable medium of claim 10, wherein the first pulse comprises a first sub-pulse of a first polarity and a second sub-pulse of a second polarity opposite the first polarity.

13. The non-transitory computer-readable medium of claim 10, wherein the method further comprises iteratively measuring the memory window metric of the ferroelectric memory device and applying a subsequent pulse to the ferroelectric memory device, wherein the subsequent pulse has a subsequent voltage magnitude determined based at least in part on the measured memory window metric.

14. The non-transitory computer-readable medium of claim 13, wherein the step of measuring the memory window metric and the step of applying the subsequent pulse to the ferroelectric memory device are iteratively performed until the measured memory window metric reaches a threshold.

15. The non-transitory computer-readable medium of claim 14, wherein the threshold comprises a first current amount and a second current amount different from the first current amount.

16. The non-transitory computer-readable medium of claim 15, wherein the first current amount is larger than the second current amount.

17. The non-transitory computer-readable medium of claim 16, wherein the first current amount is associated with a minimum amount of current associated with a first logic state of the ferroelectric memory device.

18. A method, comprising:
adapting voltage magnitudes of pulses of a pulse train applied to a ferroelectric memory device in response to respective memory window metrics measured from the ferroelectric memory device after each of the applied pulses until the measured memory window metric reaches a threshold.

19. The method of claim 18, wherein the ferroelectric memory device is a ferroelectric field-effect transistor (FeFET).

20. The method of claim 18, wherein the ferroelectric memory device comprises a hafnium-based ferroelectric material.
